(19) United States
(12) Patent Application Publication
(10) Pub. No.: US 2026/0053011 A1
(43) Pub. Date: Feb. 19, 2026

(54) SEMICONDUCTOR DEVICE, CIRCUIT BOARD, AND METHOD FOR MANUFACTURING CIRCUIT BOARD

(71) Applicants: Kabushiki Kaisha Toshiba, Kawasaki-shi (JP); Toshiba Electronic Devices & Storage Corporation, Kawasaki-shi (JP)

(72) Inventors: Kentaro MORI, Fujisawa (JP); Kazuya MARUYAMA, Tokyo (JP)

(21) Appl. No.: 19/367,157

(22) Filed: Oct. 23, 2025

Related U.S. Application Data
(63) Continuation of application No. PCT/JP2024/006720, filed on Feb. 26, 2024.

(30) Foreign Application Priority Data
Jul. 31, 2023 (JP) 2023-124558

(51) Int. Cl. H01L 23/495; H01L 23/00; H01L 23/31

(52) U.S. Cl. CPC H01L 23/4952; H01L 23/3107; H01L 23/49541; H01L 24/13; H01L 2224/13

(57) ABSTRACT

According to an embodiment, a semiconductor device having a first surface facing a first side and a second surface facing a second side opposite to the first side is provided. The semiconductor device of the embodiment includes a semiconductor device body, a lead frame to which the semiconductor device body is electrically connected, a conductive bump portion electrically connected to a semiconductor device body or the lead frame, and a resin portion configured to cover and hold at least a part of the semiconductor device body and at least a part of the lead frame. At least a part of the conductive bump portion is exposed outside the resin portion.

### CROSS-REFERENCE TO RELATED APPLICATION

This application is based upon and claims the benefit of priority from Japanese Patent Application No. 2023-124558, filed on Jul. 31, 2023; the entire contents of which are incorporated herein by reference.

### FIELD

Embodiments described herein relate generally to a semiconductor device, a circuit board, and a method for manufacturing a circuit board.

### BACKGROUND

There is a demand for thinner semiconductor devices. However, when a semiconductor device is made thinner, the handleability of the semiconductor device deteriorates. Therefore, the productivity of products using the semiconductor device may deteriorate due to the deterioration of the yield of products on which the semiconductor device is mounted, the restriction on a mounting method when the semiconductor device is mounted, and the like.

### BRIEF DESCRIPTION OF THE DRAWINGS

FIG. 1 is a cross-sectional view showing a part of a circuit board of a first embodiment.

FIG. 2 is a cross-sectional view showing a semiconductor device of the first embodiment.

FIG. 3 is a plan view showing the semiconductor device of the first embodiment.

FIG. 4 is a cross-sectional view showing a stud bump for forming a conductive bump portion of the first embodiment.

FIG. 5 is a flowchart showing a method for manufacturing the semiconductor device of the first embodiment.

FIG. 6A is a cross-sectional view showing a first accommodation portion forming step of the first embodiment.

FIG. 6B is a cross-sectional view showing a chip fixing step of the first embodiment.

FIG. 6C is a cross-sectional view showing a stud bump forming step of the first embodiment.

FIG. 6D is a cross-sectional view showing a state after the stud bump forming step of the first embodiment is performed.

FIG. 6E is a cross-sectional view showing a state after a molding step of the first embodiment is performed.

FIG. 6F is a cross-sectional view showing a state after a grinding step of the first embodiment is performed.

FIG. 7 is a plan view showing a parent material of a lead frame of the first embodiment.

FIG. 8 is a flowchart showing a method for manufacturing the circuit board according to the first embodiment.

FIG. 9A is a cross-sectional view showing a semiconductor device accommodation step of the first embodiment.

FIG. 9B is a cross-sectional view showing a state after a sealing step of the first embodiment is performed.

FIG. 9C is a cross-sectional view showing a laser processing step of the first embodiment.

FIG. 9D is a cross-sectional view showing a state after the laser processing step of the first embodiment is performed.

FIG. 10 is a cross-sectional view showing a semiconductor device of a second embodiment.

FIG. 11 is a plan view showing a semiconductor device of the second embodiment.

FIG. 12 is a cross-sectional view showing a semiconductor device of a third embodiment.

FIG. 13 is a plan view showing the semiconductor device of the third embodiment.

FIG. 14 is a cross-sectional view showing a semiconductor device of a fourth embodiment.

FIG. 15 is a flowchart showing a method for manufacturing the semiconductor device of the fourth embodiment.

FIG. 16A is a cross-sectional view showing a chip fixing step of the fourth embodiment.

FIG. 16B is a cross-sectional view showing a stud bump forming step and a vertical wire forming step of the fourth embodiment.

FIG. 16C is a cross-sectional view showing a state after a stud bump forming step and a vertical wire forming step of the fourth embodiment are performed.

FIG. 16D is a cross-sectional view showing a state after a molding step of the fourth embodiment is performed.

FIG. 16E is a cross-sectional view showing a state after a grinding step of the fourth embodiment is performed.

FIG. 17 is a cross-sectional view showing a part of a circuit board of a fifth embodiment.

FIG. 18 is a cross-sectional view showing a part of a circuit board of a sixth embodiment.

### DETAILED DESCRIPTION

According to an embodiment, a semiconductor device having a first surface facing a first side and a second surface facing a second side opposite to the first side is provided. The semiconductor device of the embodiment includes a semiconductor device body, a lead frame to which the semiconductor device body is electrically connected, a conductive bump portion electrically connected to a semiconductor device body or the lead frame, and a resin portion configured to cover and hold at least a part of the semiconductor device body and at least a part of the lead frame. At least a part of the conductive bump portion is exposed outside the resin portion.

Hereinafter, a semiconductor device, a circuit board, and a method for manufacturing a circuit board according to embodiments will be described with reference to the drawings.

In the drawings, as appropriate, a thickness direction of the circuit board of the embodiment is indicated as a Z-axis direction, a direction perpendicular to the thickness direction of the circuit board is indicated as an X-axis direction, and a direction perpendicular to both the Z-axis direction and the X-axis direction is indicated as a Y-axis direction. In the following description, the X-axis direction is referred to as a “first direction X,” the Y-axis direction is referred to as a “second direction Y,” and the Z-axis direction is referred to as a “thickness direction Z.” In addition, a side of an arrow of a Z-axis (a +Z-side) in the thickness direction Z is referred to as an “upper side” and a side (a −Z-side) opposite to the side of the arrow of the Z-axis in the thickness direction Z is referred to as a “lower side.” In addition, in the following embodiments, the upper side corresponds to a “first side” and the lower side corresponds to a “second side” opposite to the first side.

### First Embodiment

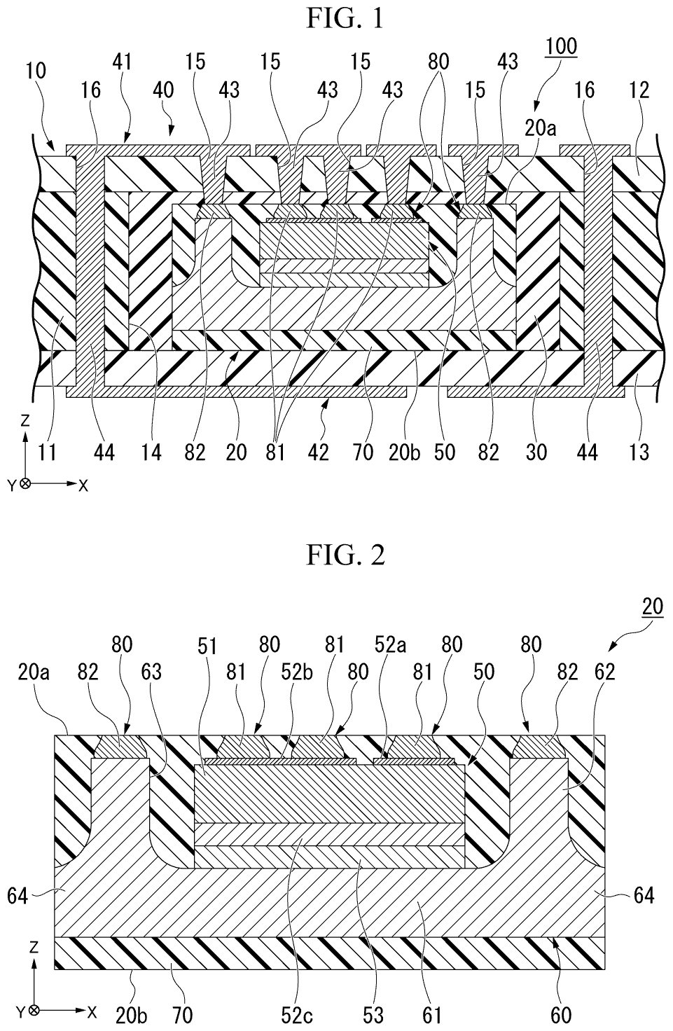

FIG. 1 is a cross-sectional view showing a part of a circuit board 100 of the first embodiment. As shown in FIG. 1, in the first embodiment, the circuit board 100 is a circuit board in which a semiconductor device 20 is embedded. The circuit board 100 includes a board body portion (board body) 10, a semiconductor device 20, and a wiring portion 40. The board body portion 10 is plate-shaped with a board surface facing the thickness direction Z. The semiconductor device 20 is mounted on the board body portion 10. The board body portion 10 has a board-shaped base material portion 11, a resin layer 12 laminated on an upper surface of the base material portion 11, a resin layer 13 laminated on a lower surface of the base material portion 11, and a sealing resin portion 30.

The base material portion 11 is formed with a second accommodation portion (second accommodation) 14 configured to accommodate the semiconductor device 20 therein. In the first embodiment, the second accommodation portion 14 is a hole penetrating the base material portion 11 in the thickness direction Z. An upper opening of the second accommodation portion 14 is blocked by the resin layer 12. A lower opening of the second accommodation portion 14 is blocked by the resin layer 13. An internal part of the second accommodation portion 14, excluding a part where the semiconductor device 20 is located, is filled with a sealing resin portion 30.

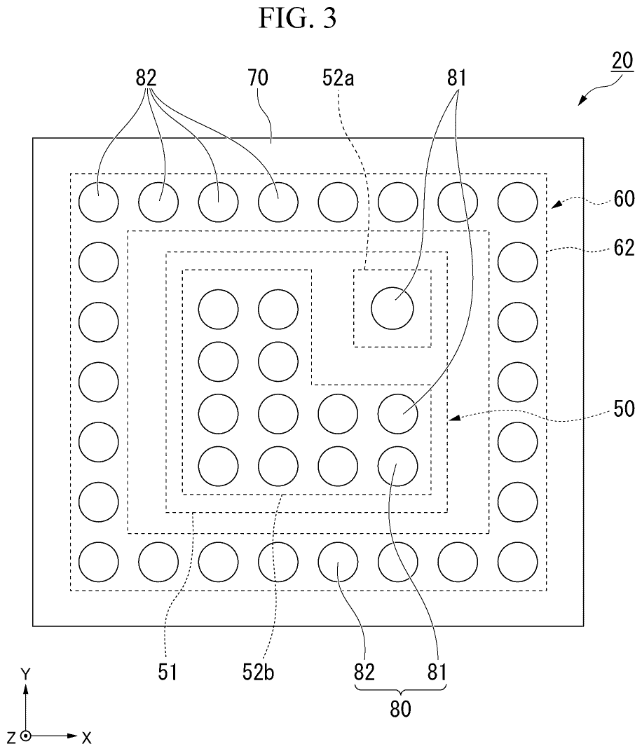

FIG. 2 is a cross-sectional view showing the semiconductor device 20 of the first embodiment. FIG. 3 is a plan view showing the semiconductor device 20 of the first embodiment. In the first embodiment, the semiconductor device 20 is, for example, a vertical-structure field effect transistor (FET). The semiconductor device 20 is, for example, a metal-oxide-semiconductor field-effect transistor (MOSFET). As shown in FIGS. 2 and 3, the semiconductor device 20 has a thin plate shape in the thickness direction Z. As shown in FIG. 3, the semiconductor device 20 is approximately square-shaped with sides in the first direction X and the second direction Y when viewed in the thickness direction Z. As shown in FIG. 2, the semiconductor device 20 includes a semiconductor device body 50, a lead frame 60, a conductive bump portion (conductive bump) 80, and a resin portion (resin) 70.

In the first embodiment, the semiconductor device body 50 is a semiconductor chip on which the electrodes of the field effect transistors are formed. The semiconductor device body 50 is accommodated inside a first accommodation portion (first accommodation) 63 of the lead frame 60, which will be described below. The semiconductor device body 50 has a board portion 51, a first metallic film 52a, a second metallic film 52b, and a third metallic film 52c. As shown in FIG. 2 and FIG. 3, the board portion 51 is plate-shaped with the board surface facing the thickness direction Z. The board portion 51 is rectangular when viewed in the thickness direction Z. The material constituting the board portion 51 is a semiconductor material. The material constituting the board portion 51 is, for example, silicon (Si), silicon carbide (SiC), gallium nitride (GaN), or the like.

The first metallic film 52a and the second metallic film 52b are formed on the upper surface of the board portion 51. The third metallic film 52c is formed on the lower surface of the board portion 51. As shown in FIG. 3, the first metallic film 52a is formed on one corner of the upper surface of the board portion 51. The first metallic film 52a is approximately square-shaped when viewed in the thickness direction Z. The second metallic film 52b is formed across the remaining three corners of the upper surface of the board portion 51. The second metallic film 52b is approximately L-shaped when viewed in the thickness direction Z. The second metallic film 52b has a part adjacent to the first metallic film 52a in the first direction X and a part adjacent to the first metallic film 52a in the second direction Y. As shown in FIG. 2, the third metallic film 52c is formed on the entire lower surface of the board portion 51.

The first metallic film 52a, the second metallic film 52b, and the third metallic film 52c are formed by, for example, sputtering. A material constituting the first metallic film 52a and a material forming the second metallic film 52b are, for example, the same as each other. The material constituting the first metallic film 52a and the material constituting the second metallic film 52b are not particularly limited as long as they have electrical conductivity, and are, for example, aluminum. A material constituting the third metallic film 52c is not particularly limited as long as it has electrical conductivity, and is, for example, a material containing one or more materials such as titanium (Ti), nickel (Ni), gold (Au), silver (Ag), and copper (Cu). The third metallic film 52c is, for example, a Ti/Ni/Au laminated film, a Ti/Ni/Ag laminated film, or the like.

In the first embodiment, the first metallic film 52a is a gate electrode. The second metallic film 52b is a source electrode. The third metallic film 52c is a drain electrode. Each metallic film may be any electrode. Moreover, the third metallic film 52c may not be an electrode. In this case, three metallic films may be formed on the upper surface of the board portion 51 and the three metallic films may correspond to a gate electrode, a source electrode, and a drain electrode.

The semiconductor device body 50 is electrically connected to the lead frame 60. The lead frame 60 is a conductive member made of metal. The material constituting the lead frame 60 is not particularly limited as long as it has conductivity, and is, for example, copper (Cu). Although not shown, a silver (Ag) coating is formed on the surface of the lead frame 60 to prevent oxidation. In addition, the coating may not be formed. The lead frame 60 has a support portion 61 configured to support the semiconductor device body 50 from below, a frame portion 62 configured to protrude upward from the support portion 61, and a protrusion portion 64 configured to protrude from the support portion 61 in a direction perpendicular to the thickness direction Z.

The semiconductor device body 50 is joined to the upper surface of the support portion 61 via a joint portion 53. The joint portion 53 is conductive. The joint portion 53 is, for example, solder, a metal paste, or the like. In the first embodiment, the joint portion 53 electrically connects the upper surface of the support portion 61 and the third metallic film 52c.

As shown in FIG. 3, in the first embodiment, the frame portion 62 has a rectangular frame shape. The frame portion 62 surrounds the semiconductor device body 50. As shown in FIG. 2, the upper surface of the frame portion 62 is arranged at the same position as the upper surface of the semiconductor device body 50 in the thickness direction Z. In addition, the upper surface of the frame portion 62 may be located above the upper surface of the semiconductor device body 50 or may be located below the upper surface of the semiconductor device body 50.

The support portion 61 and the frame portion 62 form a first accommodation portion 63 that opens upward. In the first embodiment, the upper surface of the frame portion 62 is an opening periphery part of the first accommodation portion 63 within the upper surface of the lead frame 60. The protrusion portion 64 is connected to the support portion 61. A plurality of protrusion portions 64 are provided. The plurality of protrusion portions 64 include a protrusion portion 64 configured to protrude from the support portion 61 in the first direction X and a protrusion portion 64 configured to protrude from the support portion 61 in the second direction Y.

The conductive bump portion 80 is a bump having electrical conductivity. In addition, in the present specification, for example, it is only necessary for the “conductive bump portion,” to have a part in which a conductive material is formed as a lump having a certain thickness. The “certain thickness” is, for example, a thickness greater than the thickness of a film generally formed by sputtering and the thickness of a film generally formed by plating processing. In the first embodiment, the dimension of the conductive bump portion 80 in the thickness direction Z is greater than 4 μm. As an example, the dimension of the conductive bump portion 80 in the thickness direction Z is approximately 10 μm or more and 50 μm or less. The dimension of the conductive bump portion 80 in the thickness direction Z is not particularly limited.

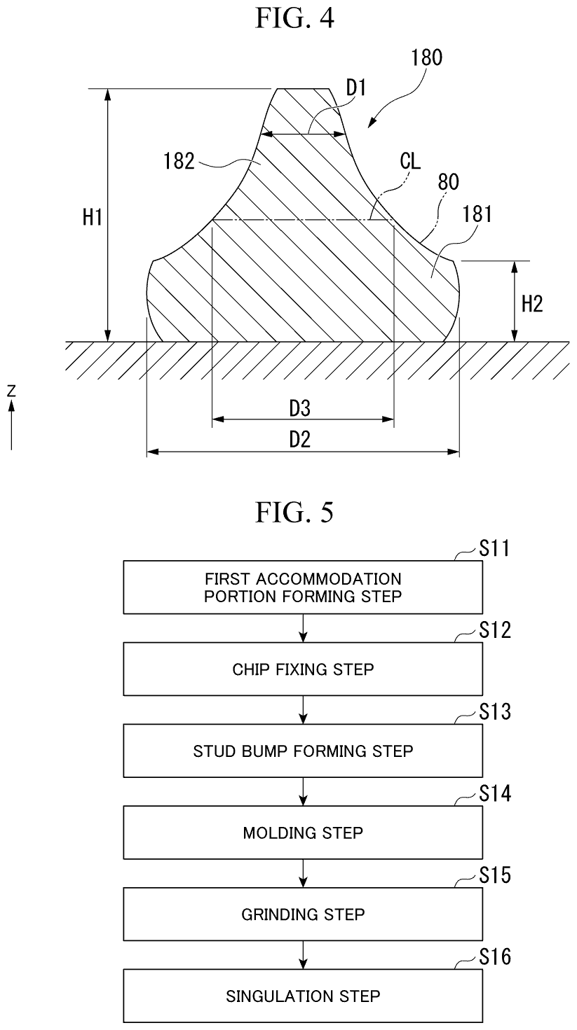

In the first embodiment, the conductive bump portion 80 is formed by a stud bump. The stud bump is formed by performing ball bonding using a bonding wire and then cutting the bonding wire. FIG. 4 is a cross-sectional view showing a stud bump 180 for forming the conductive bump portion 80. The stud bump 180 has an approximately conical shape with an outer diameter that decreases toward the upper side. The stud bump 180 has a base portion 181 joined to a target to which the stud bump 180 is connected and a reduced diameter portion 182 protruding from the base portion 181. The outer diameter of the reduced diameter portion 182 decreases as a distance from the base portion 181 increases.

An outer diameter D1 shown in FIG. 4 is an outer diameter of the bonding wire. For example, an outer diameter of a part of an upper portion of the reduced diameter portion 182 is equal to the outer diameter D1 of the bonding wire. The outer diameter D1 of the bonding wire is not particularly limited, but is, for example, approximately 20 μm or more and 100 μm or less. An outer diameter D2 of the base portion 181 is, for example, approximately two times or more and approximately three times or less than the outer diameter D1 of the bonding wire. A height H2 of the base portion 181 is, for example, approximately one-fifth of the outer diameter D2 of the base portion 181. A height H1 of the stud bump 180 can be arbitrarily increased by overlapping ball bonding. The conductive bump portion 80 of the first embodiment is formed by cutting a part of the reduced diameter portion 182 of the stud bump 180. Specifically, for example, the conductive bump portion 80 is formed by cutting a part of the reduced diameter portion 182 of the stud bump 180 along a virtual line CL shown in FIG. 4. In the example of FIG. 4, the virtual line CL is located at a part of the reduced diameter portion 182 whose outer diameter is larger than the outer diameter D1 of the bonding wire. Therefore, an outer diameter D3 at the upper end of the conductive bump portion 80 is smaller than the outer diameter D2 of the base portion 181 and larger than the outer diameter D1 of the bonding wire.

Because the conductive bump portion 80 is formed by cutting a part of the upper portion of the stud bump 180, the conductive bump portion 80 has an approximately truncated cone shape with an outer diameter that decreases toward the upper side. An upper end surface of the conductive bump portion 80 is a flat surface perpendicular to the thickness direction Z. A material constituting the conductive bump portion 80 is not particularly limited as long as it has conductivity, and may be, for example, gold (Au), silver (Ag), copper (Cu), or the like. From the viewpoint of ease in forming the stud bump 180, for example, it is preferable to select gold (Au) as the material constituting the conductive bump portion 80. From the viewpoint of reducing the manufacturing cost, for example, it is preferable to select copper (Cu) as the material constituting the conductive bump portion 80.

As shown in FIG. 2, the conductive bump portion 80 includes first conductive bump portions (first conductive bumps) 81 and second conductive bump portions (second conductive bumps) 82. The first conductive bump portion 81 is electrically connected to the semiconductor device body 50. More specifically, the first conductive bump portion 81 is connected to the upper surface of the semiconductor device body 50. A plurality of first conductive bump portions 81 are provided. The plurality of first conductive bump portions 81 include a first conductive bump portion 81 electrically connected to the first metallic film 52a and a first conductive bump portion 81 electrically connected to the second metallic film 52b. As shown in FIG. 3, for example, only one first conductive bump portion 81 electrically connected to the first metallic film 52a is provided. In addition, two or more first conductive bump portions 81 electrically connected to the first metallic film 52a may be provided. A plurality of first conductive bump portions 81 electrically connected to the second metallic film 52b are provided. A plurality of first conductive bump portions 81 electrically connected to the second metallic film 52b are aligned in the first direction X and the second direction Y and arranged to be laid on the approximately L-shaped second metallic film 52b.

As shown in FIG. 2, the second conductive bump portion 82 is electrically connected to the lead frame 60. In the first embodiment, the second conductive bump portion 82 is electrically connected to the upper surface of the frame portion 62. In other words, the second conductive bump portion 82 is connected to an opening periphery part of the first accommodation portion 63 on the upper surface of the lead frame 60. The second conductive bump portion 82 is electrically connected to the third metallic film 52c via the lead frame 60 and the joint portion 53. A plurality of second conductive bump portions 82 are provided. As shown in FIG. 3, in the first embodiment, the plurality of second conductive bump portions 82 are aligned and arranged in a rectangular frame shape along the frame portion 62. The plurality of second conductive bump portions 82 are arranged to surround the first conductive bump portions 81 when viewed from above.

In the first embodiment, the material constituting the first conductive bump portion 81 and the material constituting the second conductive bump portion 82 are the same as each other. Moreover, in the first embodiment, the material constituting the first conductive bump portion 81 and the material constituting the second conductive bump portion 82 are different from the material constituting the lead frame 60.

As shown in FIG. 2, the resin portion 70 covers and holds at least a part of the semiconductor device body 50 and at least a part of the lead frame 60. In the first embodiment, the resin portion 70 covers the entire semiconductor device body 50, the entire lead frame 60, excluding a distal end surface of the protrusion portion 64, and the entire conductive bump portion 80, excluding an upper end surface. In the first embodiment, the semiconductor device body 50, the lead frame 60, and the conductive bump portions 80 are embedded and held in the resin portion 70. In the first embodiment, the resin portion 70 is formed by resin molding using a mold.

The upper surface of the resin portion 70 constitutes a part of the first surface 20a facing the upper side of the semiconductor device 20. The resin portion 70 covers the entire lower surface of the lead frame 60. The lower surface of the resin portion 70 is the second surface 20b facing the lower side of the semiconductor device 20. At least a part of the conductive bump portion 80 is exposed outside the resin portion 70. In the first embodiment, the upper end surfaces of the plurality of conductive bump portions 80 are exposed outside the resin portion 70. More specifically, the upper end surfaces of the plurality of conductive bump portions 80 are exposed on the first surface 20a of the semiconductor device 20. In the first embodiment, the first surface 20a is formed by the upper surface of the resin portion 70 and the upper end surfaces of the plurality of conductive bump portions 80. The material constituting the resin portion 70 is not particularly limited as long as it is a resin having insulating properties. The material constituting the resin portion 70 may be a molded resin or an interlayer insulating material.

In the first embodiment, the upper end surface of the first conductive bump portion 81 and the upper end surface of the second conductive bump portion 82 are exposed on the first surface 20a. That is, the end surface of the first conductive bump portion 81 and the end surface of the second conductive bump portion 82 are exposed on the same surface of the semiconductor device 20. As shown in FIG. 3, in the first embodiment, the upper end surface of the first conductive bump portion 81 and the upper end surface of the second conductive bump portion 82 are circular. The first conductive bump portion 81 connected to the first metallic film 52a functions as a gate electrode of the semiconductor device 20 when its upper end surface is exposed outside the resin portion 70. The first conductive bump portion 81 connected to the second metallic film 52b functions as a source electrode of the semiconductor device 20 when its upper end surface is exposed outside the resin portion 70. The second conductive bump portion 82, electrically connected to the third metallic film 52c via the lead frame 60 and the joint portion 53, functions as a drain electrode of the semiconductor device 20 when its upper end surface is exposed outside the resin portion 70.

As shown in FIG. 1, the semiconductor device 20 is accommodated in the second accommodation portion 14 of the board body portion 10 and embedded in the board body portion 10. The second surface 20b of the semiconductor device 20 is in contact with the upper surface of the resin layer 13. The first surface 20a of the semiconductor device 20 is arranged downward, away from the lower surface of the resin layer 12. A part of the sealing resin portion 30 is interposed between the first surface 20a and the resin layer 12 in the thickness direction Z.

The wiring portion 40 is a portion forming at least a part of a circuit pattern formed on the circuit board 100. The wiring portion 40 has a first wiring pattern 41 formed on the upper surface of the board body portion 10 and a second wiring pattern 42 formed on the lower surface of the board body portion 10. The wiring portion 40 is electrically connected to a part of the conductive bump portion 80 exposed outside the resin portion 70 through a hole 15 formed in the board body portion 10. The hole 15 extends from an outer surface of the board body portion 10 to a part of the conductive bump portion 80 exposed outside the resin portion 70. In the first embodiment, the hole 15 is a hole recessed downward from the upper surface of the board body portion 10. The hole 15 penetrates the resin layer 12 and a part of the sealing resin portion 30 located on the upper side of the semiconductor device 20 in the thickness direction Z. The inner diameter of the hole 15, for example, is smaller toward the lower side. The hole 15 is formed by a hole drilling process using laser light. A plurality of holes 15 are formed. The plurality of holes 15 are located above the plurality of conductive bump portions 80. At the lower end of each hole 15, the upper end surface of each conductive bump portion 80 is exposed.

The wiring portion 40 has a connection wiring portion 43 formed in the hole 15. The connection wiring portion 43 is provided for each of the plurality of holes 15. The connection wiring portion 43 is electrically connected to the conductive bump portion 80. More specifically, a lower end of each connection wiring portion 43 is electrically connected to the upper end surface of each conductive bump portion 80 exposed in each hole 15. The upper end of each connection wiring portion 43 is connected to the first wiring pattern 41. In the first embodiment, the connection wiring portion 43 is filled in the hole 15. The connection wiring portion 43 may be a conductive film formed on an inner circumferential surface of the hole 15.

The wiring portion 40 has a connection wiring portion 44 that connects the first wiring pattern 41 and the second wiring pattern 42. The connection wiring portion 44 is formed in a through hole 16 penetrating the board body portion 10 in the thickness direction Z. In the first embodiment, the connection wiring portion 44 fills the through hole 16. In addition, the connection wiring portion 44 may be a conductive film formed on an inner circumferential surface of the through hole 16.

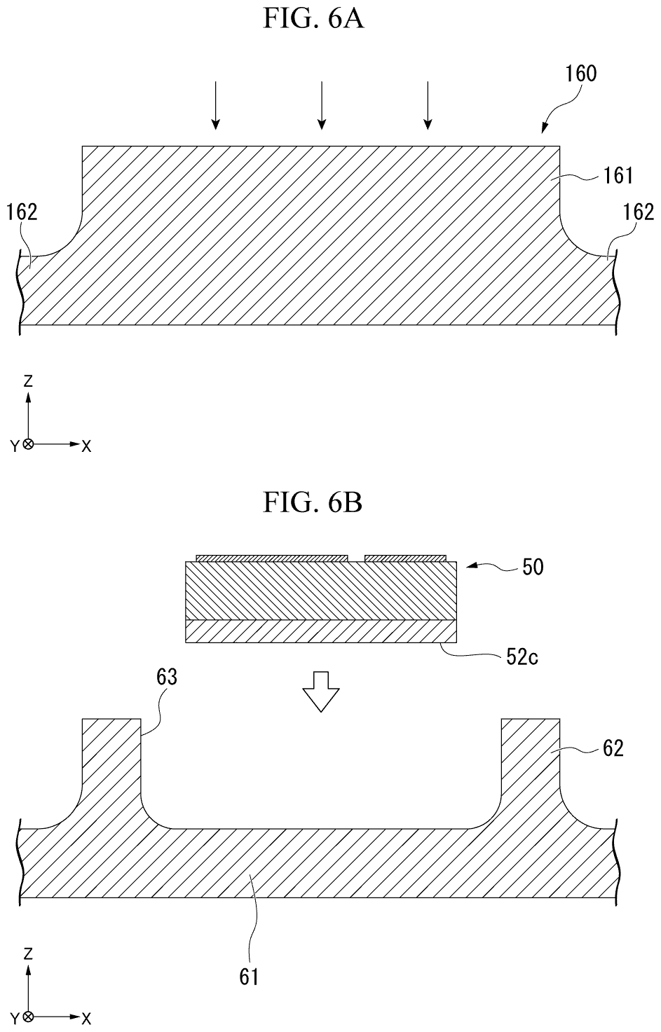

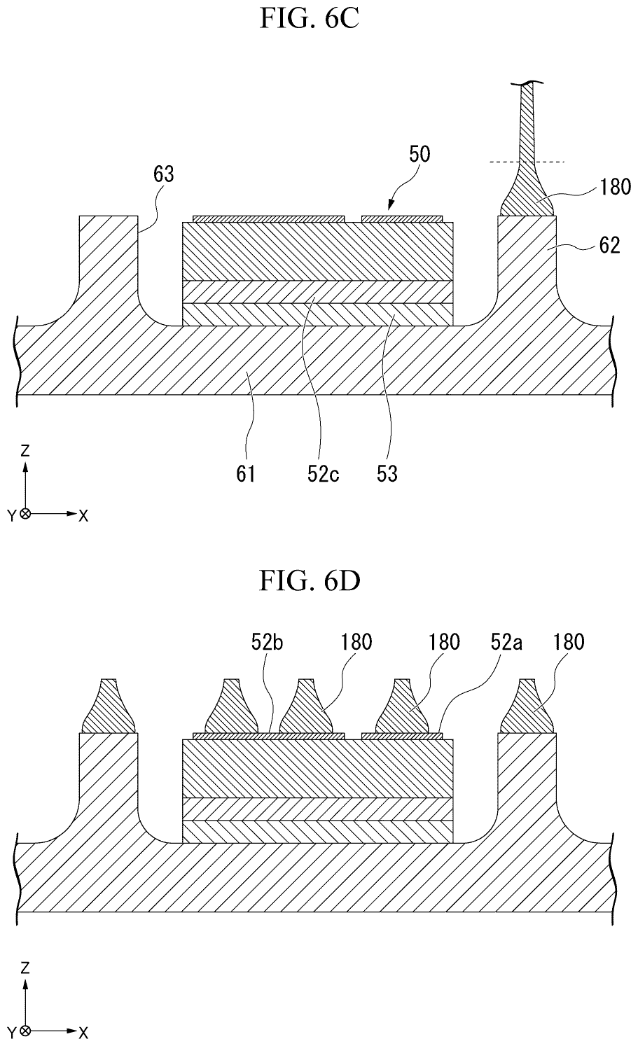

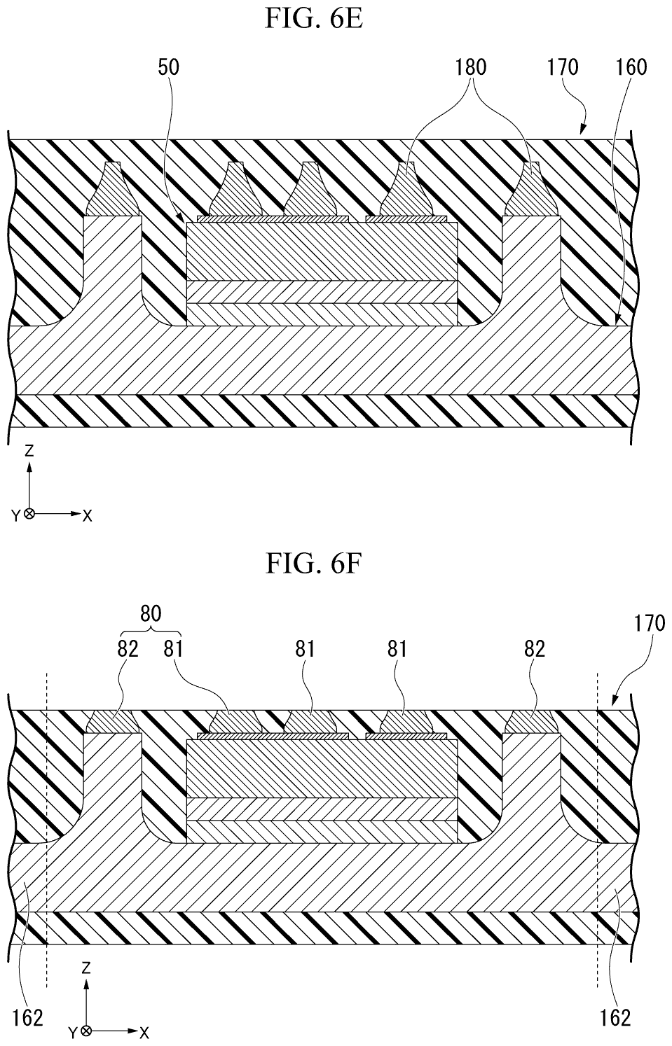

FIG. 5 is a flowchart showing a method for manufacturing the semiconductor device 20 of the first embodiment. As shown in FIG. 5, the method for manufacturing the semiconductor device 20 includes a first accommodation portion forming step S11, a chip fixing step S12, a stud bump forming step S13, a molding step S14, a grinding step S15, and a singulation step S16. FIG. 6A is a cross-sectional view showing the first accommodation portion forming step S11. FIG. 6B is a cross-sectional view showing the chip fixing step S12. FIG. 6C is a cross-sectional view showing the stud bump forming step S13. FIG. 6D is a cross-sectional view showing a state after the stud bump forming step S13 is performed. FIG. 6E is a cross-sectional view showing a state after the molding step S14 is performed. FIG. 6F is a cross-sectional view showing a state after the grinding step S15 is performed.

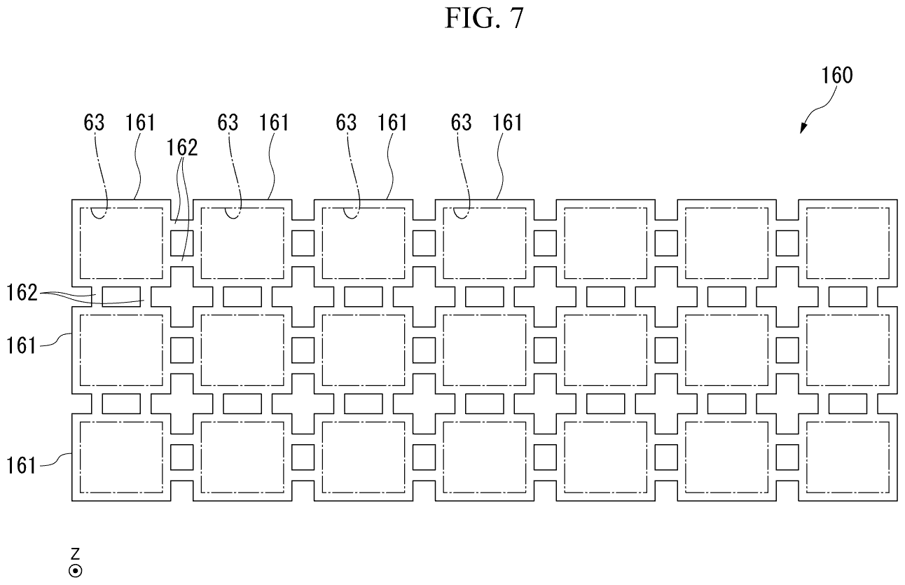

As shown in FIG. 6A, the first accommodation portion forming step S11 is a step of forming the first accommodation portion 63 in a parent material 160 for forming the lead frame 60. FIG. 7 is a plan view showing the parent material 160. The parent material 160 has a plurality of frame body portions 161. The plurality of frame body portions 161 are arranged in a matrix. Adjacent frame body portions 161 are connected to each other by two connection portions 162. As shown in FIG. 6A, a dimension of the connection portion 162 in the thickness direction Z is smaller than a dimension of the frame body portion 161 in the thickness direction Z. The connection portion 162 is connected to the lower end of the frame body portion 161. In the first accommodation portion forming step S11 of the first embodiment, the first accommodation portion 63 recessed downward is formed in each frame body portion 161 by an etching process. As shown in FIG. 6B, when the first accommodation portion 63 is formed, the support portion 61 and the frame portion 62 are formed on each frame body portion 161.

The chip fixing step S12 is a step of fixing the semiconductor device body 50 in the first accommodation portion 63. As shown in FIGS. 6B and 6C, in the chip fixing step S12, the semiconductor device body 50 is accommodated in the first accommodation portion 63 from above and fixed to the support portion 61 by the joint portion 53. In the chip fixing step S12, the semiconductor device bodies 50 are fixed one by one in the first accommodation portions 63 formed in the frame body portions 161 of the parent material 160.

As shown in FIGS. 6C and 6D, the stud bump forming step S13 is a step of forming a plurality of stud bumps 180 on the upper surface of the semiconductor device body 50 and the upper surface of the frame portion 62. As described above, the stud bumps 180 are formed by performing ball bonding using a bonding wire and then cutting the bonding wire. The stud bumps 180 formed on the upper surface of the semiconductor device body 50 are stud bumps 180 that form the first conductive bump portion 81. The stud bumps 180 formed on the upper surface of the frame portion 62 are stud bumps 180 that form the second conductive bump portion 82.

The molding step S14 is a step of performing insert molding using the parent material 160, to which the semiconductor device body 50 is fixed and on which the stud bumps 180 are formed, as an insert member. As shown in FIG. 6E, in the molding step S14, the parent material 160, the semiconductor device body 50, and the resin portion 170 in which the stud bumps 180 are embedded are formed.

The grinding step S15 is a step of grinding the resin portion 170 from above to reduce the dimension of the resin portion 170 in the thickness direction Z. In the grinding step S15, the resin portion 170 is ground until the dimension of the resin portion 170 in the thickness direction Z becomes the dimension of the semiconductor device 20 in the thickness direction Z. As shown in FIG. 6F, in the grinding step S15, the resin portion 170 is ground from above, such that the stud bump 180 is exposed on the upper surface of the resin portion 170. In the grinding step S15, an upper part of the stud bump 180 is also ground together with the resin portion 170. In the grinding step S15, the upper part of the stud bump 180 is ground and removed, such that each stud bump 180 becomes the conductive bump portion 80.

The singulation step S16 is a process in which the resin portion 170 and the parent material 160 are diced to separate each frame body portion 161 into individual pieces. In the singulation step S16, each connection portion 162 is cut and the parent material 160 is separated into individual pieces. Thereby, a plurality of semiconductor devices 20 are manufactured.

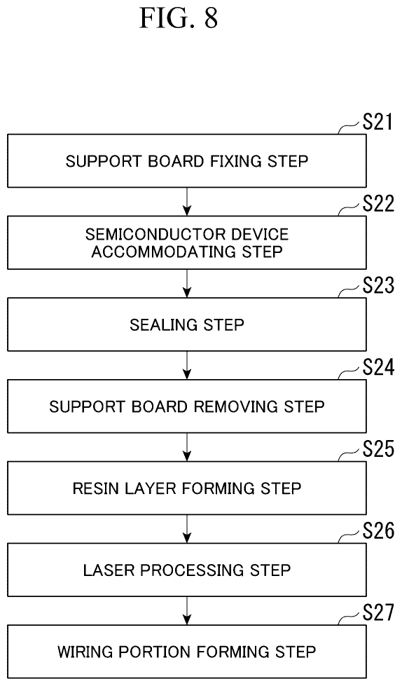

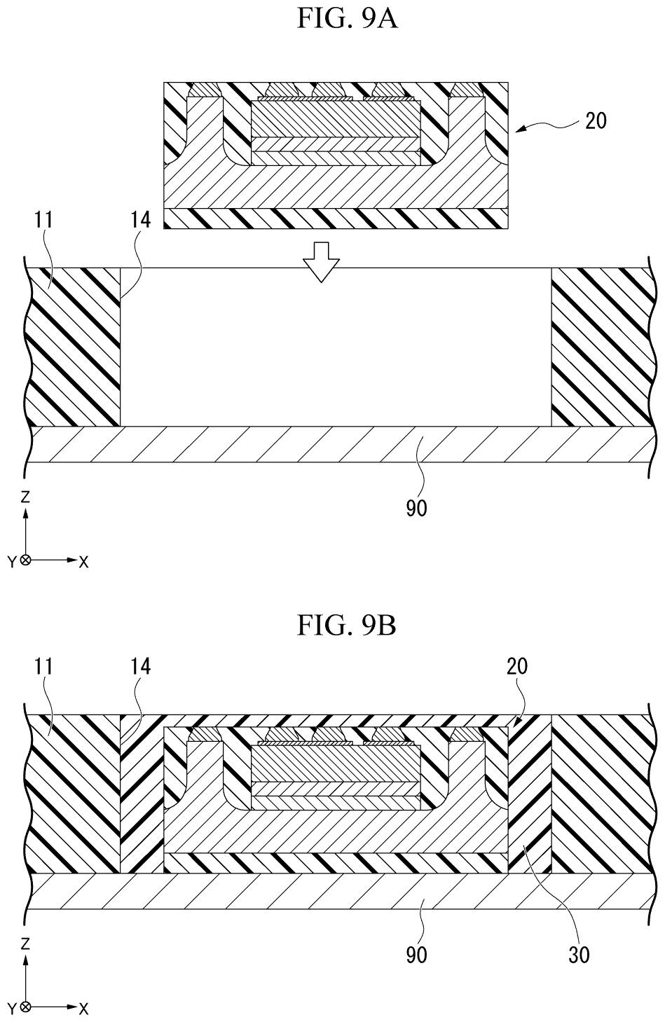

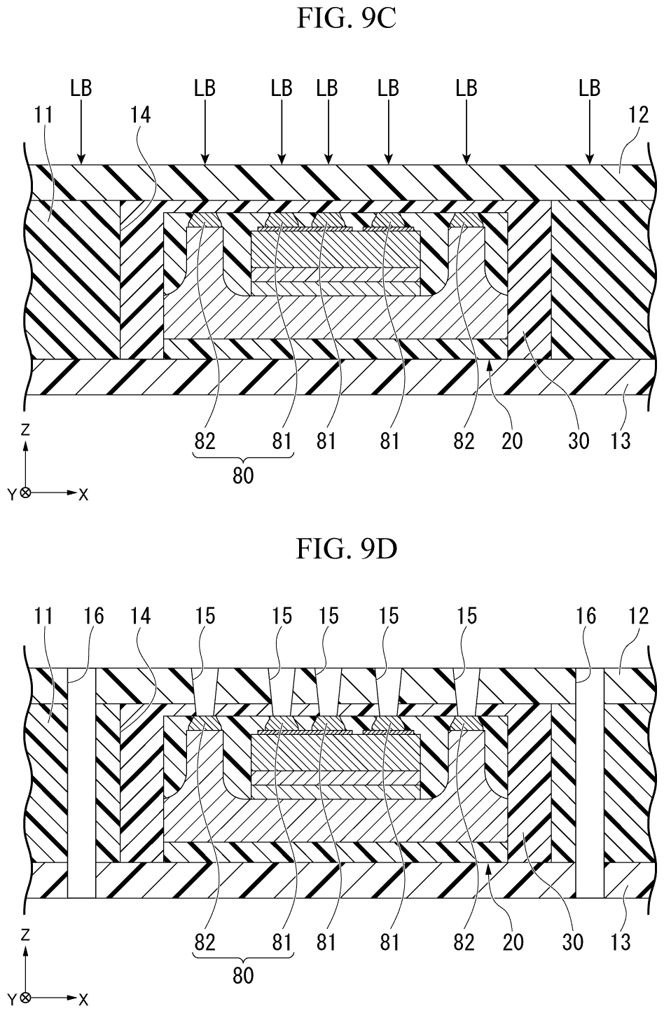

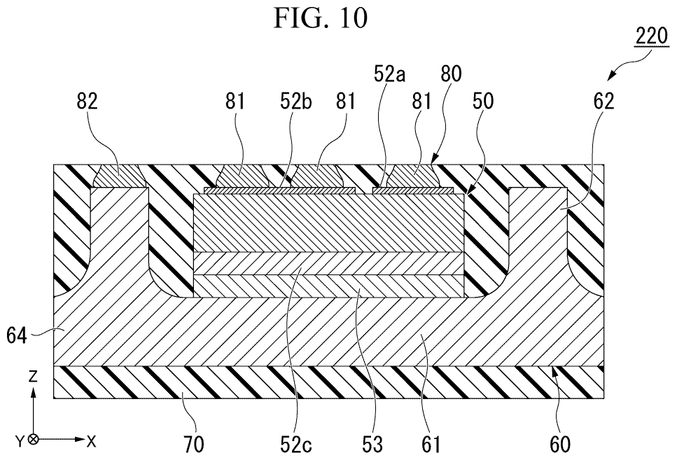

FIG. 8 is a flowchart showing a method for manufacturing the circuit board 100 of the first embodiment. As shown in FIG. 8, the method for manufacturing the circuit board 100 includes a support board fixing step S21, a semiconductor device accommodating step S22, a sealing step S23, a support board removing step S24, a resin layer forming step S25, a laser processing step S26, and a wiring portion forming step S27. FIG. 9A is a cross-sectional view showing the semiconductor device accommodating step S22. FIG. 9B is a cross-sectional view showing a state after the sealing step S23 is performed. FIG. 9C is a cross-sectional view showing the laser processing step S26. FIG. 9D is a cross-sectional view showing a state after the laser processing step S26 is performed.

The support board fixing step S21 is a step of fixing the support board 90 to the base material portion 11 in which the second accommodation portion 14 is formed. The support board 90 is plate-shaped with a board surface facing the thickness direction Z. The support board 90 is made of, for example, stainless steel. In addition, the material constituting the support board 90 is not particularly limited. Although not shown in the drawing, an adhesive layer is formed on the upper surface of the support board 90. In the support board fixing step S21, the support board 90 is fixed to the lower surface of the base material portion 11 via the adhesive layer. Thereby, as shown in FIG. 9A, a lower opening of the second accommodation portion 14 is blocked by the support board 90.

The semiconductor device accommodating step S22 is a step of accommodating the semiconductor device 20 in the second accommodation portion 14. As shown in FIG. 9A, in the semiconductor device accommodating step S22, the semiconductor device 20 is inserted into the second accommodation portion 14 through an upper opening of the second accommodation portion 14. As shown in FIG. 9B, the semiconductor device 20 inserted into the second accommodation portion 14 is placed on the upper surface of the support board 90 and fixed onto the support board 90 via an adhesive layer formed on the support board 90.

The sealing step S23 is a step of sealing the second accommodation portion 14 with resin. In the sealing step S23, the resin is poured into the second accommodation portion 14 with the semiconductor device 20 accommodated therein, to form the sealing resin portion 30. By forming the sealing resin portion 30, the semiconductor device 20 is embedded in the sealing resin portion 30 and is fixed to the base material portion 11 via the sealing resin portion 30. The support board removing step S24 is a step of removing the support board 90 from the base material portion 11. There is no particular restriction on the method for removing the support board 90 in the support board removing step S24.

The resin layer forming step S25 is a step of forming a pair of resin layers 12 and 13. In the resin layer forming step S25, the pair of resin layers 12 and 13 are formed, for example, simultaneously. In addition, in the resin layer forming step S25, the pair of resin layers 12 and 13 may be formed sequentially. By the resin layer forming step S25, as shown in FIG. 9C, the resin layer 12 is formed on the upper surface of the base material portion 11 and the resin layer 13 is formed on the lower surface of the base material portion 11.

The laser processing step S26 is a step of forming the hole 15 and the through hole 16 by radiating the laser light LB. As shown in FIG. 9C, in the laser processing step S26, the laser light LB is radiated from the upper side to the lower side of the resin layer 12. The laser light LB forming the hole 15 is radiated toward the conductive bump portion 80. The laser light LB radiated from the upper side of the resin layer 12 toward the conductive bump portion 80 penetrates the resin layer 12 and a part of the sealing resin portion 30 located above the conductive bump portion 80, and is radiated to the conductive bump portion 80. The laser light LB is blocked by the conductive bump portion 80. In the first embodiment, the conductive bump portion 80 functions as an absorption layer for the laser light LB. Thereby, the hole 15, which reaches from the upper surface of the resin layer 12 to the conductive bump portion 80, is formed. The laser light LB forming the through hole 16 is radiated to a position that does not overlap the second accommodation portion 14 in the thickness direction Z. The laser light LB for forming the through hole 16 penetrates the resin layer 12, the base material portion 11, and the resin layer 13 in the thickness direction Z to form the through hole 16. According to the laser processing step S26, a plurality of holes 15 and a plurality of through holes 16 are formed as shown in FIG. 9D. In addition, the through hole 16 may be formed using a drill instead of the laser light LB. In this case, the shape of the through hole 16 becomes a straight shape with an approximately uniform inner diameter.

The wiring portion forming step S27 is a step of forming the wiring portion 40. In the wiring portion forming step S27, for example, a metallic layer is formed on the upper surface of the resin layer 12, the lower surface of the resin layer 13, the inside of the hole 15, and the inside of the through hole 16 by plating processing, thereby forming the wiring portion 40. Through the above steps, the circuit board 100 of the first embodiment shown in FIG. 1 is manufactured.

According to the first embodiment, the semiconductor device 20 having the first surface 20a facing upward and a second surface 20b facing downward, the semiconductor device 20 including: the semiconductor device body 50; the lead frame 60 to which the semiconductor device body 50 is electrically connected; the conductive bump portion 80 electrically connected to a semiconductor device body 50 or the lead frame 60; and the resin portion 70 configured to cover and hold at least a part of the semiconductor device body 50 and at least a part of the lead frame 60. At least a part of the conductive bump portion 80 is exposed outside the resin portion 70. Therefore, even if the semiconductor device body 50 is covered with the resin portion 70, the semiconductor device body 50 can be electrically connected to other members via the conductive bump portion 80 exposed outside the resin portion 70. Thereby, the semiconductor device 20 can be a packaged semiconductor device in which the semiconductor device body 50 fixed to the lead frame 60 is covered with the resin portion 70. By packaging the semiconductor device 20 including the lead frame 60 and the resin portion 70 as well as the semiconductor device body 50, the semiconductor device 20 can be easily handled even if the semiconductor device body 50 is thinned. Therefore, the handleability of the semiconductor device 20 can be improved. Thereby, it is possible to improve the yield of products on which the semiconductor device 20 is mounted and improve the productivity of products on which the semiconductor device 20 is mounted. In the first embodiment, the yield when the circuit board 100 is manufactured by mounting the semiconductor device 20 on the board body portion 10 can be improved, and the productivity of the circuit board 100 can be improved.

Moreover, when the lead frame 60 is electrically connected to an electrode of the semiconductor device body 50, a position of the electrode to which the external terminal is connected in the semiconductor device 20 can be freely designed. Specifically, for example, in the first embodiment, the lead frame 60 is connected to the third metallic film 52c as a drain electrode provided on the lower surface of the semiconductor device body 50, and the second conductive bump portion 82 connected to the lead frame 60 is exposed on the upper first surface 20a, such that the drain electrode of the semiconductor device 20 can be arranged on the upper surface of the semiconductor device 20. Thereby, a gate electrode, a source electrode, and a drain electrode can be provided on the upper surface of the semiconductor device 20. Therefore, while the semiconductor device body 50 is a field effect transistor with a vertical structure, the semiconductor device 20 as a whole can be handled as a field effect transistor with a horizontal structure. Thus, when a degree of freedom in the arrangement of the electrodes to which the external terminals are connected in the semiconductor device 20 can be improved, a mounting method according to the product on which the semiconductor device 20 is mounted can be easily adopted and the productivity of the product on which the semiconductor device 20 is mounted can be further improved. In the first embodiment, the productivity of the circuit board 100 in which the semiconductor device 20 is embedded can be further improved.

Moreover, the heat of the semiconductor device body 50 can be easily released to the outside via the lead frame 60. Therefore, the heat dissipation of the semiconductor device 20 can be improved. Moreover, the conductive bump portion 80 has a larger dimension in the thickness direction Z and a larger heat capacity than a conductive film formed by, for example, plating processing. Therefore, when the conductive bump portion 80 is connected to the semiconductor device body 50, for example, it is possible to easily transfer heat from the semiconductor device body 50 to the conductive bump portion 80, compared to when a conductive film formed by plating processing is provided on the semiconductor device body 50 instead of the conductive bump portion 80. Thereby, it is possible to easily release heat from the semiconductor device body 50 to the outside, and further improve the heat dissipation of the semiconductor device 20.

Moreover, when a conductive film is formed by plating processing on the lower surface of the thin semiconductor device body 50, the use of the plating processing complicates the process and is technically difficult. In contrast, in the first embodiment, because the lead frame 60 can be fixed to the lower surface of the semiconductor device body 50, it is not necessary to form a conductive film by plating processing on the lower surface of the semiconductor device body 50.

Moreover, according to the first embodiment, the conductive bump portion 80 includes the first conductive bump portion 81 electrically connected to the semiconductor device body 50 and the second conductive bump portion 82 electrically connected to the lead frame 60. Therefore, it is possible to easily electrically connect other members to the semiconductor device body 50 and the lead frame 60 from outside the semiconductor device 20 via the first conductive bump portion 81 and the second conductive bump portion 82.

Moreover, according to the first embodiment, the end surface of the first conductive bump portion 81 and the end surface of the second conductive bump portion 82 are exposed on the same surface of the semiconductor device 20. Therefore, the work of electrically connecting another member or the like to each of the first conductive bump portion 81 and the second conductive bump portion 82 can be easily performed compared to when the first conductive bump portion 81 and the second conductive bump portion 82 are exposed on different surfaces of the semiconductor device 20. Thereby, it is possible to further improve the productivity of the product on which the semiconductor device 20 is mounted. Moreover, because the work of forming the first conductive bump portion 81 and the second conductive bump portion 82 can be performed from the same side, the man-hours required for manufacturing the semiconductor device 20 can be reduced. Thereby, it is possible to improve the productivity of the semiconductor device 20.

Moreover, according to the first embodiment, the first conductive bump portion 81 is connected to the upper surface of the semiconductor device body 50. The lead frame 60 has the first accommodation portion 63 that opens upward. The semiconductor device body 50 is accommodated inside the first accommodation portion 63. The second conductive bump portion 82 is connected to the opening periphery part of the first accommodation portion 63 within the upper surface of the lead frame 60. The upper end surface of the first conductive bump portion 81 and the upper end surface of the second conductive bump portion 82 are exposed on the first surface 20a. Therefore, it is easy to align the positions of the upper surface of the semiconductor device body 50 and the opening periphery part of the first accommodation portion 63 within the upper surface of the lead frame 60 in the thickness direction Z, and the first conductive bump portion 81 and the second conductive bump portion 82 are easily made by similar methods. Specifically, in the first embodiment, the first conductive bump portion 81 and the second conductive bump portion 82 can be formed by forming a similar stud bump 180. Thereby, it is possible to easily form the first conductive bump portion 81 and the second conductive bump portion 82.

Moreover, according to the first embodiment, the conductive bump portion 80 is formed by a stud bump. In other words, the first conductive bump portion 81 and the second conductive bump portion 82 are formed by stud bumps. Therefore, the first conductive bump portion 81 and the second conductive bump portion 82 can be easily formed by ball bonding using a bonding wire. Thereby, it is possible to reduce the number of steps required to form a conductive portion electrically connected to the semiconductor device body 50 or the lead frame 60, compared to when a conductive film is formed by plating processing instead of the conductive bump portion 80. Therefore, the manufacturing cost of the semiconductor device 20 can be reduced.

Moreover, according to the first embodiment, a plurality of second conductive bump portions 82 are provided, and the plurality of second conductive bump portions 82 are arranged to surround the first conductive bump portion 81 when viewed from above. Thus, it is possible to easily connect an external terminal or the like to the second conductive bump portion 82. Moreover, thereby, it is possible to efficiently dissipate heat in a large area from the third metallic film 52c serving as the drain electrode to the side (the upper side) on which the semiconductor device 20 is mounted.

Moreover, according to the first embodiment, the material constituting the first conductive bump portion 81 and the material constituting the second conductive bump portion 82 are the same as each other and different from the material constituting the lead frame 60. For example, a configuration in which the conductive bump portion 80 is not connected to the lead frame 60 and the lead frame 60 itself is exposed outside the resin portion 70 to serve as a terminal portion of the semiconductor device 20 is also conceivable. In this case, in the above-described grinding step S15, when the resin portion 170 is ground, a part of the conductive bump portion 80 and a part of the lead frame 60 are ground together with the resin portion 170, such that a part of the conductive bump portion 80 and a part of the lead frame 60 are exposed outside the resin portion 70. At this time, if the material constituting the conductive bump portion 80 and the material constituting the lead frame 60 are different from each other, because it becomes necessary to grind three different types of materials including the resin portion 170, it is difficult to perform grinding processing in some cases. In contrast, in the first embodiment, the second conductive bump portion 82 connected to the lead frame 60 is provided and the second conductive bump portion 82 is formed from the same material as the first conductive bump portion 81, such that the number of other types of materials to be ground when the resin portion 170 is ground in the grinding step S15 can be reduced to one. Therefore, the grinding processing can be easily performed in the grinding step S15. Moreover, when the material constituting the first conductive bump portion 81 and the material constituting the second conductive bump portion 82 are the same as each other, it is possible to easily produce a plurality of conductive bump portions 80.

Moreover, according to the first embodiment, the semiconductor device 20 is embedded in the board body portion 10. Therefore, a length of the wiring connecting the electrodes of the semiconductor device 20 and the wiring pattern formed on the board body portion 10 can be easily shortened compared to when the semiconductor device 20 is attached to the board surface of the board body portion 10 and the electrode of the semiconductor device 20 are connected to the wiring pattern formed on the board body portion 10 by wire bonding or the like. Thereby, the resistance between the electrodes of the semiconductor device 20 and the wiring pattern formed on the board body portion 10 can be easily reduced and an electric current can easily flow between the electrodes of the semiconductor device 20 and the wiring pattern formed on the board body portion 10. Therefore, the circuit board 100 can be easily made into a circuit board that can also adapt to high-speed communication in which high-frequency electrical signals flow. Moreover, the circuit board 100 can be made smaller in size compared to when the semiconductor device 20 is attached to the board surface of the board body portion 10 and the electrodes of the semiconductor device 20 are connected to the wiring pattern formed on the board body portion 10 by wire bonding or the like. Moreover, it is also possible to form other layers in the thickness direction Z and mount another device on a part of the board body portion 10 in which the semiconductor device 20 is embedded, and the like. Thereby, it is possible to improve the degree of freedom in designing the circuit board 100.

Moreover, according to the first embodiment, the board body portion 10 has a second accommodation portion 14 configured to accommodate the semiconductor device 20 therein. The hole 15 extending from the outer surface of the board body portion 10 to a part of the conductive bump portion 80 exposed outside the resin portion 70 is formed in the board body portion 10. Inside the hole 15, the connection wiring portion 43 electrically connected to the conductive bump portion 80 is formed. When such a hole 15 is formed, the board body portion 10 is processed using, for example, the above-described laser processing and the like to form the hole 15. At this time, it is necessary to provide an absorption layer that receives the laser light LB on the upper surface of the semiconductor device body 50 and the like to prevent the laser light LB from damaging the semiconductor device body 50 and the like. When this absorption layer is a thin film formed by, for example, sputtering and the like, there is a risk that the laser light LB will penetrate the thin film and damage the semiconductor device body 50 and the like. In contrast, in the first embodiment, the conductive bump portion 80, which can be made larger to a certain extent in the thickness direction Z, can be used as an absorption layer for the laser light LB. Therefore, when the hole 15 is formed by laser processing, the laser light LB can be appropriately received by the conductive bump portion 80, and damage to the semiconductor device body 50 and the like can be suppressed.

Moreover, for example, a conductive film having a certain large dimension in the thickness direction Z can be formed on the semiconductor device body 50 by plating processing or the like, and the conductive film can be used as an absorption layer for the laser light LB when the hole 15 is processed. However, a step of forming a conductive film by plating processing tends to require many steps, and the manufacturing cost of the semiconductor device 20 tends to increase. Moreover, the conductive film formed by plating processing may not be thick enough to serve as an absorption layer. In contrast, in the first embodiment, instead of the conductive film formed by plating processing, the conductive bump portion 80 thicker than the conductive film is formed. The number of steps to form the conductive bump portion 80 tends to be less than the number of steps to form the conductive film by plating processing. Therefore, the increase in the manufacturing cost of the semiconductor device 20 can be suppressed. Moreover, a sufficient thickness for an absorption layer is easily obtained by the conductive bump portion 80.

Moreover, according to the first embodiment, the manufacturing method for manufacturing the circuit board 100 includes forming the hole 15 by irradiating the conductive bump portion 80 with the laser light LB. Therefore, as described above, the conductive bump portion 80 can be used as an absorption layer, and the laser light LB can be suitably prevented from penetrating the conductive bump portion 80. Thereby, it is possible to suitably suppress the damage to the semiconductor device body 50 and the like due to the laser light LB.

### Second Embodiment

The number of second conductive bump portions 82 in a second embodiment is different from that in the first embodiment. In the following description, constituent elements similar to those in the above-described embodiments may be denoted by the same reference signs as appropriate and the description thereof may be omitted.

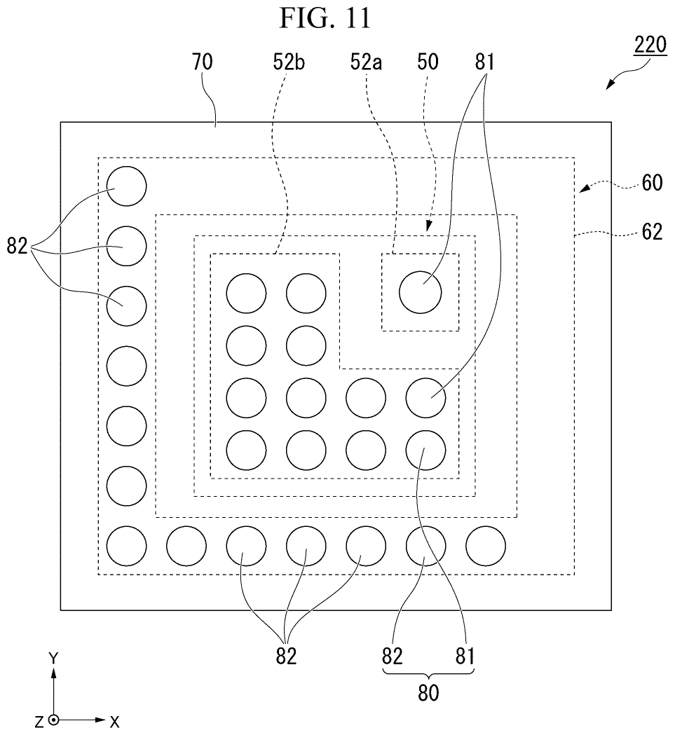

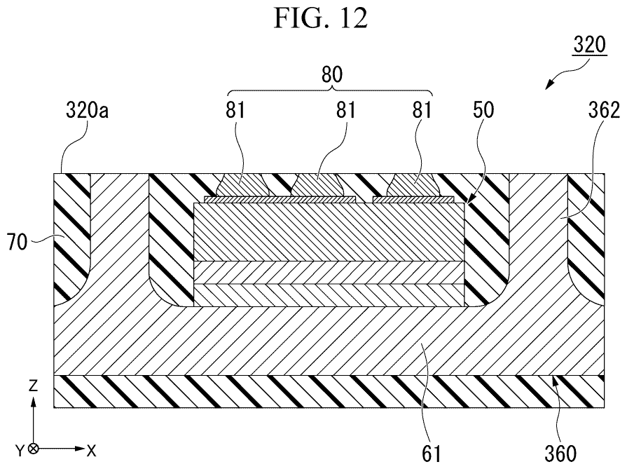

FIG. 10 is a cross-sectional view showing a semiconductor device 220 of the second embodiment. FIG. 11 is a plan view showing the semiconductor device 220 of the second embodiment. As shown in FIGS. 10 and 11, the semiconductor device 220 has a smaller number of second conductive bump portions 82 than the semiconductor device 20 of the first embodiment. Specifically, as shown in FIG. 11, a plurality of second conductive bump portions 82 are aligned and arranged in an L-shape along two sides of a rectangular frame portion 62. In other words, the second conductive bump portions 82 are not provided on the other two sides of the rectangular frame portion 62. In this way, it is possible to suppress the interference of the second conductive bump portion 82 with the routing of wiring in the circuit board on which the semiconductor device 220 is mounted by employing a configuration in which the second conductive bump portions 82 are not provided on one or more of the four sides of the frame portion 62 in a state in which the plurality of second conductive bump portions 82 are not arranged in a frame shape. Therefore, the degree of freedom of routing of wiring on the circuit board on which the semiconductor device 220 is mounted can be improved. The other configuration of the semiconductor device 220 is similar to that of the semiconductor device 20 of the first embodiment.

### Third Embodiment

A third embodiment is different from the first embodiment in that there is no second conductive bump portion 82. In the following description, constituent elements similar to those in the above-described embodiments may be denoted by the same reference signs as appropriate and the description thereof may be omitted.

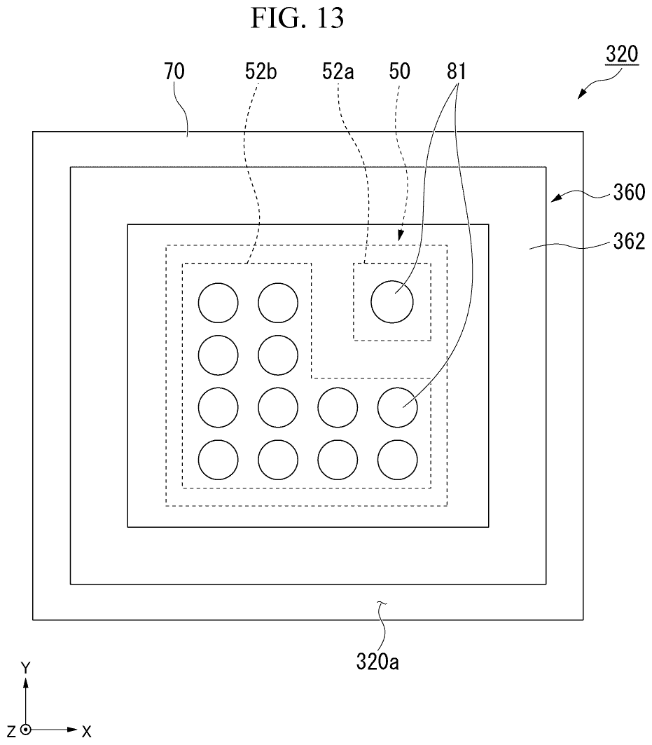

FIG. 12 is a cross-sectional view showing a semiconductor device 320 of the third embodiment. FIG. 13 is a plan view showing the semiconductor device 320 of the third embodiment. As shown in FIGS. 12 and 13, unlike the semiconductor device 20 of the first embodiment, the semiconductor device 320 does not have a second conductive bump portion 82 connected to a lead frame 360. As shown in FIG. 12, an upper end surface of a frame portion 362 in the lead frame 360 is located above an upper surface of a semiconductor device body 50. The upper end surface of the frame portion 362 is exposed on a first surface 320a on an upper side of the semiconductor device 320. In the third embodiment, the first surface 320a includes an upper surface of a resin portion 70, an upper end surface of a first conductive bump portion 81, and the upper end surface of the frame portion 362. In the third embodiment, the upper end surface of the frame portion 362 can be used as an absorption layer when a laser processing step S26 is performed.

In the third embodiment, a material constituting the lead frame 360 is the same as a material constituting the first conductive bump portion 81. Therefore, when a grinding step S15 is performed, the number of types of materials to be ground other than the resin portion 70 can be reduced to only one and the grinding process can be easily performed. When the material constituting the lead frame 360 and the material constituting the first conductive bump portion 81 are the same as each other, the material is preferably copper (Cu), for example, from the viewpoint of manufacturing costs. In addition, in the third embodiment, the material constituting the lead frame 360 and the material constituting the first conductive bump portion 81 may be different from each other. The other configuration of the semiconductor device 320 is similar to that of the semiconductor device 20 of the first embodiment.

### Fourth Embodiment

A fourth embodiment is different from the first embodiment in the shape of a second conductive bump portion 482. In the following description, constituent elements similar to those in the above-described embodiments may be denoted by the same reference signs as appropriate and the description thereof may be omitted.

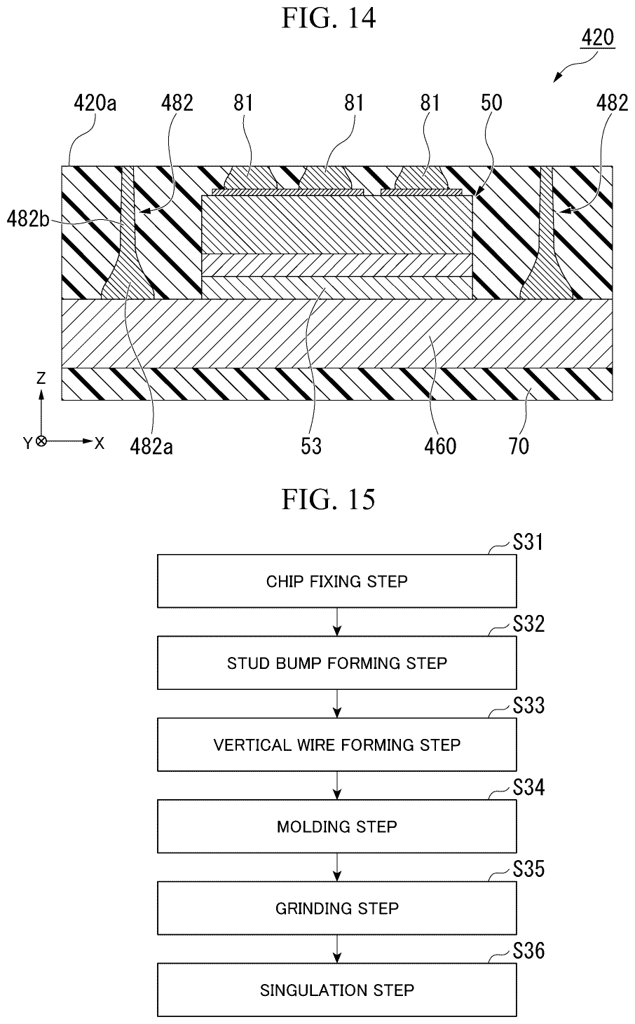

FIG. 14 is a cross-sectional view showing a semiconductor device 420 of the fourth embodiment. As shown in FIG. 14, a first accommodation portion 63 is not formed on a lead frame 460 of a semiconductor device 420. The lead frame 460 is a flat plate whose plate surface faces the thickness direction Z.

In the fourth embodiment, a second conductive bump portion 482 is formed by a vertical wire 480a. The vertical wire 480a is formed by performing ball bonding using the bonding wire and then extending the bonding wire in a vertical direction from the stud bump formed by ball bonding and cutting the bonding wire at a certain length. The second conductive bump portion 482 is connected to the upper surface of the lead frame 460.

The second conductive bump portion 482 has a stud bump portion 482a connected to the lead frame 460 and a wire portion 482b extending upward from the stud bump portion 482a. The stud bump portion 482a is a portion formed by a stud bump. The stud bump portion 482a has the same shape as the stud bump 180 described in the first embodiment. The stud bump portion 482a is connected to the upper surface of the lead frame 460. In the fourth embodiment, the stud bump portion 482a and the semiconductor device body 50 are fixed to the same surface of the lead frame 460. In other words, the second conductive bump portion 482 and the semiconductor device body 50 are fixed to the same surface of the lead frame 460. The wire portion 482b is a portion formed by a bonding wire. The upper end surface of the wire portion 482b is exposed on the first surface 420a. The other configuration of the semiconductor device 420 is similar to that of the semiconductor device 20 of the first embodiment.

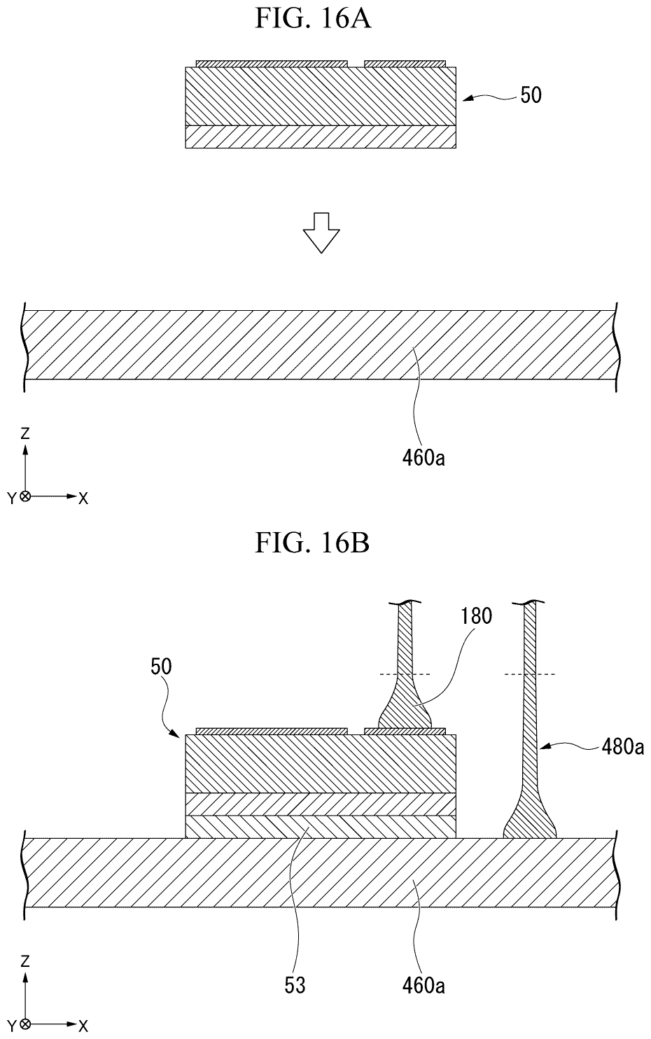

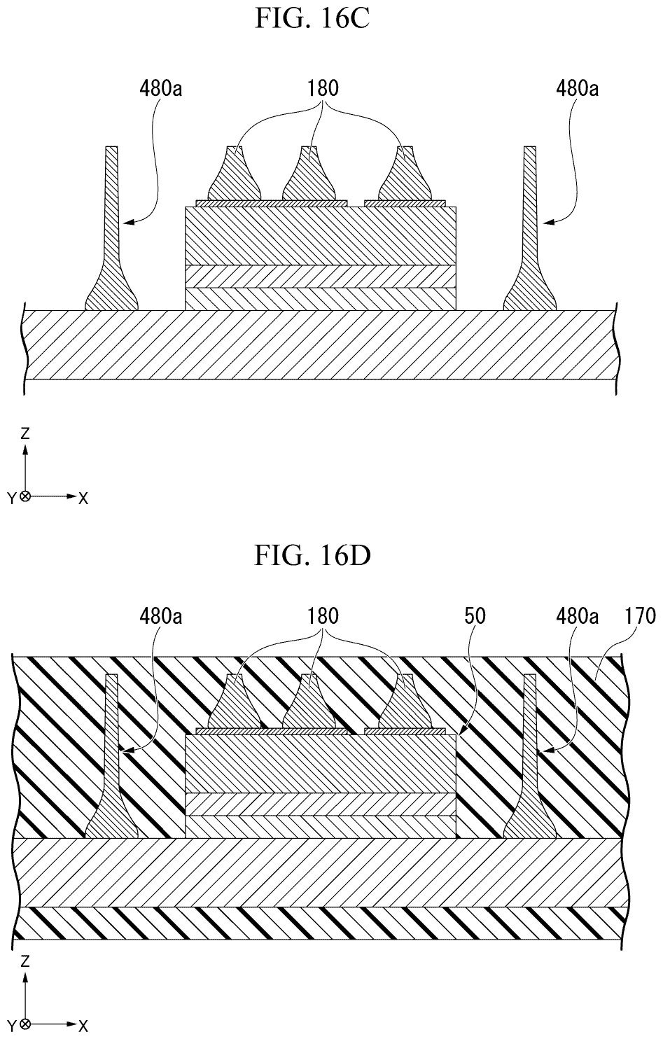

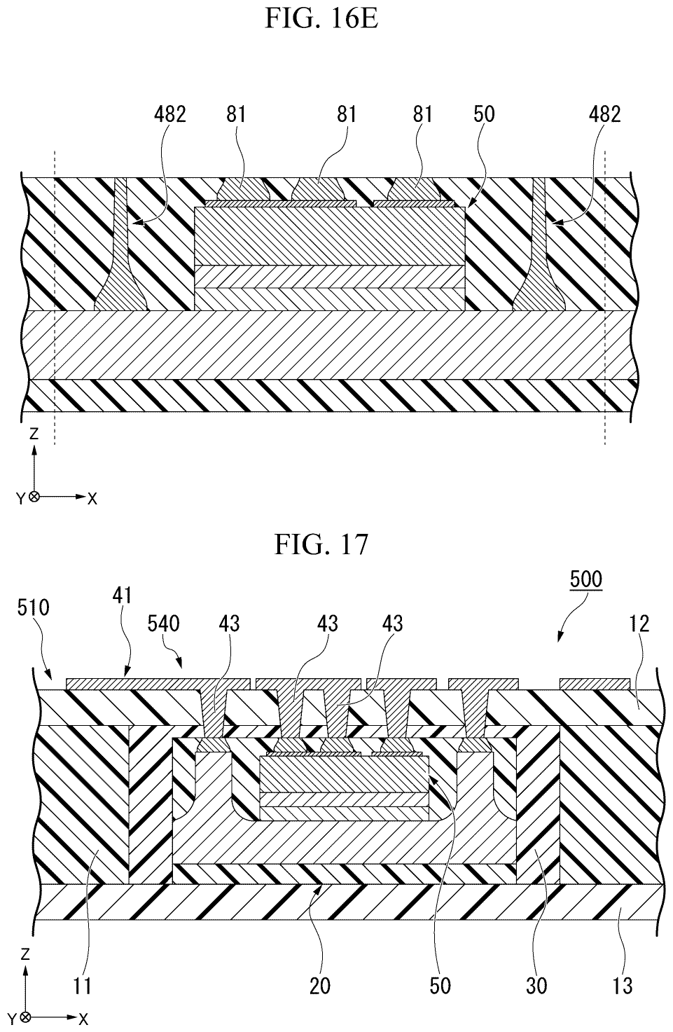

FIG. 15 is a flowchart showing a method for manufacturing the semiconductor device 420 of the fourth embodiment. As shown in FIG. 15, the method for manufacturing the semiconductor device 420 includes a chip fixing step S31, a stud bump forming step S32, a vertical wire forming step S33, a molding step S34, a grinding step S35, and a singulation step S36. FIG. 16A is a cross-sectional view showing the chip fixing step S31. FIG. 16B is a cross-sectional view showing the stud bump forming step S32 and the vertical wire forming step S33. FIG. 16C is a cross-sectional view showing a state after the stud bump forming step S32 and the vertical wire forming step S33 are performed. FIG. 16D is a cross-sectional view showing a state after the molding step S34 is performed. FIG. 16E is a cross-sectional view showing a state after the grinding step S35 is performed.

As shown in FIG. 16A, the chip fixing step S31 is a step of fixing the semiconductor device body 50 to a parent material 460a of the lead frame 460. The parent material 460a, for example, is similar to the parent material 160 of the first embodiment, except that the dimension in the thickness direction Z is the same throughout. The parent material 460a may be the same parent material as the parent material 160 of the first embodiment. In the chip fixing step S31, the semiconductor device body 50 is fixed to the upper surface of the parent material 460a by the joint portion 53. In the chip fixing step S31, the semiconductor device bodies 50 are fixed to the plurality of frame body portions formed on the parent material 460a one by one.

The stud bump forming step S32 is similar to the stud bump forming step S13 in the first embodiment, except that only a first conductive bump portion 81 is formed. As shown in FIGS. 16B and 16C, the vertical wire forming step S33 is a step of forming a vertical wire 480a on the parent material 460a of a lead frame 460. As described above, the vertical wire 480a is formed by performing ball bonding using a bonding wire and then extending the bonding wire in a vertical direction from the stud bump formed by ball bonding and cutting the bonding wire at a certain length.

Although the case where the stud bump forming step S32 and the vertical wire forming step S33 are performed simultaneously is shown in FIG. 16B, the present invention is not limited thereto. The vertical wire forming step S33 may be performed after the stud bump forming step S32 is completed, the stud bump forming step S32 may be performed after the vertical wire forming step S33 is completed, or the stud bump forming step S32 and the vertical wire forming step S33 may be performed simultaneously.

The molding step S34 is a step of performing insert molding using the parent material 460a, to which the semiconductor device body 50 is fixed and on which the stud bump 180 and the vertical wire 480a are formed, as an insert member. As shown in FIG. 16D, the resin portion 170 in which the parent material 460a, the semiconductor device body 50, the stud bump 180, and the vertical wire 480a are embedded is formed by the molding step S34.

The grinding step S35 is a step of grinding the resin portion 170 from above to reduce the dimension of the resin portion 170 in the thickness direction Z. In the grinding step S35, the resin portion 170 is ground until the dimension of the resin portion 170 in the thickness direction Z becomes the dimension of the semiconductor device 420 in the thickness direction Z. As shown in FIG. 16E, the resin portion 170 is ground from above by the grinding step S35, such that the stud bump 180 and the vertical wire 480a are exposed on the upper surface of the resin portion 170. In the grinding step S35, an upper part of the stud bump 180 and an upper part of a wire portion of the vertical wire 480a are also ground together with the resin portion 170. In the grinding step S35, the upper part of the stud bump 180 is ground and removed, such that each stud bump 180 becomes the first conductive bump portion 81. In the grinding step S35, the upper part of the wire portion of the vertical wire 480a is ground and removed, such that each vertical wire 480a becomes the second conductive bump portion 482.

The singulation step S36 is similar to the singulation step S16 of the first embodiment. A plurality of semiconductor devices 420 are formed by the singulation step S36. The other steps in the method for manufacturing the semiconductor device 420 are similar to those in the method for manufacturing the semiconductor device 20 of the first embodiment.

According to the fourth embodiment, the second conductive bump portion 482 has the stud bump portion 482a connected to the lead frame 460 and the wire portion 482b extending upward from the stud bump portion 482a. The upper end surface of the wire portion 482b is exposed on the first surface 420a. In this way, when the second conductive bump portion 482 is formed by the vertical wire 480a, a position of the upper end of the second conductive bump portion 482 connected to the lead frame 460 can be made to be the same as a position of the upper end of the first conductive bump portion 81 without forming the first accommodation portion 63 in the lead frame 460. Therefore, the number of steps for processing the lead frame 460 can be reduced.

### Fifth Embodiment

A fifth embodiment is different from the first embodiment in the shape of a wiring portion 540. In the following description, constituent elements similar to those in the above-described embodiments may be denoted by the same reference signs as appropriate and the description thereof may be omitted.

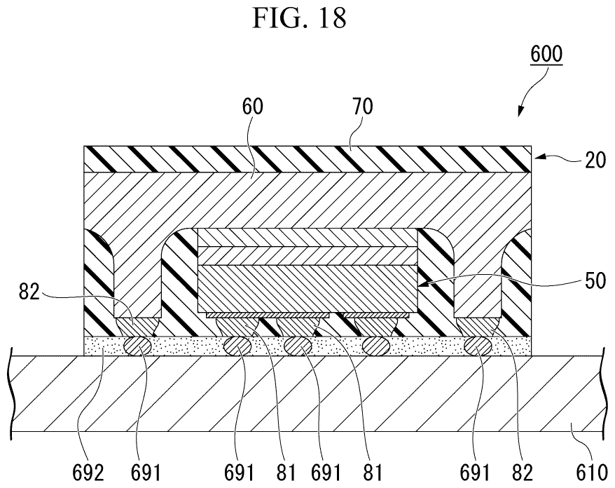

FIG. 17 is a cross-sectional view showing a part of a circuit board 500 of the fifth embodiment. As shown in FIG. 17, a through hole 16 is not formed in a board body portion 510 of the circuit board 500. The wiring portion 540 of the circuit board 500 does not have a second wiring pattern 42 and a connection wiring portion 44 formed in a through hole 16. The other configuration of the wiring portion 540 is similar to that of the wiring portion 40 of the first embodiment. The other configuration of the circuit board 500 is similar to that of the circuit board 100 of the first embodiment.

### Sixth Embodiment

A sixth embodiment is different from the first embodiment in that a circuit board 600 does not incorporate a semiconductor device 20. In the following description, constituent elements similar to those in the above-described embodiments may be denoted by the same reference signs as appropriate and the description thereof may be omitted.

FIG. 18 is a cross-sectional view showing a part of a circuit board 600 of the sixth embodiment. As shown in FIG. 18, in the sixth embodiment, the semiconductor device 20 is attached to a board surface of the board body portion 610. The semiconductor device 20 is mounted on the board body portion 610 by flip-chip mounting. A first conductive bump portion 81 and a second conductive bump portion 82 of the semiconductor device 20 are electrically connected to a wiring pattern (not shown) on the board body portion 610 via a bump 691 formed by solder or the like. An adhesive layer 692 for adhering the semiconductor device 20 to the board body portion 610 is formed between the semiconductor device 20 and the board body portion 610. A plurality of bumps 691 are embedded in the adhesive layer 692.

According to the sixth embodiment, the semiconductor device 20 is attached to one board surface of the board body portion 610. Therefore, a structure of the board body portion 610 can be simplified compared to when the semiconductor device 20 is embedded in the board body portion 610.

Moreover, when the semiconductor device body 50 is made thinner, the handleability of the semiconductor device body 50 deteriorates. Because of this, conventionally, there has been a problem that it is difficult to mount the semiconductor device body 50 on the board body portion 610 by flip-chip mounting. Moreover, there is a structural constraint such as the need to form the semiconductor device body 50 as a field effect transistor with a horizontal structure so that flip-chip mounting is performed. In contrast, the semiconductor device body 50 and the lead frame 60 are covered with a resin portion 70 to be packaged, and the handleability of the semiconductor device 20 is improved, such that the semiconductor device 20 can be easily mounted on the board body portion 610 by flip-chip mounting. Moreover, even if the semiconductor device body 50 is a field effect transistor with a vertical structure, a gate electrode, a source electrode, and a drain electrode of the semiconductor device 20 can be provided on the same surface via the lead frame 60, such that flip-chip mounting can be adopted as a mounting method for the semiconductor device 20 regardless of the structure of the semiconductor device body 50.

According to at least one of the embodiments described above, a semiconductor device having a first surface facing a first side and a second surface facing a second side opposite to the first side is provided. The semiconductor device includes a semiconductor device body, a lead frame to which the semiconductor device body is electrically connected, a conductive bump portion electrically connected to a semiconductor device body or the lead frame, and a resin portion configured to cover and hold at least a part of the semiconductor device body and at least a part of the lead frame. At least a part of the conductive bump portion is exposed outside the resin portion. Thereby, it is possible to improve the handleability of the semiconductor device.

The conductive bump portion is not limited to the conductive bump portion formed by the stud bump and the conductive bump portion formed by the vertical wire described above. A method for forming the conductive bump portion is not particularly limited. The conductive bump portion may be formed by a metallic bump formed by screen printing or may be formed by a metallic bump formed by an inkjet method. The conductive bump portion may be entirely exposed outside the resin portion.

As the conductive bump portion, only the first conductive bump portion may be provided or only the second conductive bump portion may be provided. The number of conductive bump portions is not particularly limited as long as it is one or more. A surface of the semiconductor device on which the first conductive bump portion is exposed and a surface of the semiconductor device on which the second conductive bump portion is exposed may be different surfaces. When a plurality of first conductive bump portions are provided, the plurality of first conductive bump portions may include two or more first conductive bump portions exposed on different surfaces of the semiconductor device. When a plurality of second conductive bump portions are provided, the plurality of second conductive bump portions may include two or more second conductive bump portions exposed on different surfaces of the semiconductor device. The material constituting the first conductive bump portion and the material constituting the second conductive bump portion may be different from each other.

A configuration of the circuit board on which the semiconductor device is provided is not particularly limited. The circuit board may be a multi-layer board. The number of semiconductor devices provided on the circuit board is not particularly limited as long as it is one or more. The hole formed in the circuit board may be formed by a method other than laser processing. In this case, it is also possible to suppress the damage to the semiconductor device body and the like by forming a conductive bump portion having a certain thickness.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device having a first surface facing a first side and a second surface facing a second side opposite to the first side, the semiconductor device comprising:
a semiconductor device body;
a lead frame to which the semiconductor device body is electrically connected;
a conductive bump electrically connected to a semiconductor device body or the lead frame; and
a resin configured to cover and hold at least a part of the semiconductor device body and at least a part of the lead frame,
wherein at least a part of the conductive bump is exposed outside the resin.

2. The semiconductor device of claim 1, comprising a plurality of conductive bumps including the conductive bump,
wherein the plurality of conductive bumps include
a first conductive bump electrically connected to the semiconductor device body; and
a second conductive bump electrically connected to the lead frame.

3. The semiconductor device of claim 2, wherein an end surface of the first conductive bump and an end surface of the second conductive bump are exposed on the same surface of the semiconductor device.

4. The semiconductor device of claim 3,
wherein the first conductive bump is connected to a surface of the first side of the semiconductor device body,
wherein the lead frame has a first accommodation that opens to the first side,
wherein the semiconductor device body is accommodated inside the first accommodation,
wherein the second conductive bump is connected to an opening periphery part of the first accommodation within a surface of the first side of the lead frame, and
wherein an end surface of the first side of the first conductive bump and an end surface of the first side of the second conductive bump are exposed on the first surface.

5. The semiconductor device of claim 4, wherein the first conductive bump and the second conductive bump are formed by stud bumps.

6. The semiconductor device of claim 3,
wherein the first conductive bump is connected to a surface of the first side of the semiconductor device body,
wherein the second conductive bump is connected to a surface of the first side of the lead frame,
wherein the first conductive bump is formed by a stud bump,
wherein the second conductive bump has
a stud bump portion connected to the lead frame; and
a wire portion extending from the stud bump portion to the first side, and
wherein an end surface of the first side of the first conductive bump and an end surface of the first side of the wire portion are exposed on the first surface.

7. The semiconductor device of claim 1, wherein the conductive bump is formed by a stud bump.

8. The semiconductor device of claim 4,
wherein the plurality of conductive bumps include a plurality of second conductive bumps including the second conductive bump, and
wherein the plurality of second conductive bumps are arranged to surround the first conductive bump when viewed from the first side.

9. The semiconductor device of claim 2, wherein a material constituting the first conductive bump and a material constituting the second conductive bump are the same as each other and different from a material constituting the lead frame.

10. A circuit board comprising:
a semiconductor device having a first surface facing a first side and a second surface facing a second side opposite to the first side; and
a board body on which the semiconductor device is mounted,
wherein the semiconductor device includes
a semiconductor device body;
a lead frame to which the semiconductor device body is electrically connected;
a conductive bump electrically connected to the semiconductor device body or the lead frame; and
a resin configured to cover and hold at least a part of the semiconductor device body and at least a part of the lead frame,
wherein at least a part of the conductive bump is exposed outside the resin.

11. The circuit board according to claim 10, wherein the semiconductor device is embedded in the board body.

12. The circuit board according to claim 11,
wherein the board body has a second accommodation configured to accommodate the semiconductor device therein,
wherein a hole extending from an outer surface of the board body to a part of the conductive bump exposed outside the resin is formed in the board body, and
wherein a connection wiring portion electrically connected to the conductive bump is formed in the hole.

13. The circuit board according to claim 10, wherein the semiconductor device is attached to a board surface of the board body.

14. A method for manufacturing a circuit board,
wherein the circuit board includes
a semiconductor device having a first surface facing a first side and a second surface facing a second side opposite to the first side; and
a board body on which the semiconductor device is mounted,
wherein the semiconductor device includes
a semiconductor device body;
a lead frame to which the semiconductor device body is electrically connected;
a conductive bump electrically connected to a semiconductor device body or the lead frame; and
a resin configured to cover and hold at least a part of the semiconductor device body and at least a part of the lead frame,
wherein the semiconductor device is embedded in the board body,
wherein at least a part of the conductive bump is exposed outside the resin,
wherein the board body has an accommodation portion configured to accommodate the semiconductor device therein,
wherein a hole extending from an outer surface of the board body to a part of the conductive bump exposed outside the resin is formed in the board body,
wherein a connection wiring portion electrically connected to the conductive bump is formed in the hole, and
wherein the method for manufacturing the circuit board includes forming the hole by irradiating the conductive bump with laser light.
